(19) United States
(12) Patent Application Publication
(10) Pub. No.: US 2026/0353599 A1
(43) Pub. Date: Nov. 5, 2026

(54) HEATSINK FOR IMMERSION COOLING

(71) Applicant: HEWLETT PACKARD ENTERPRISE DEVELOPMENT LP, Spring, TX (US)

(72) Inventors: Austin Edward Rodriguez, The Woodlands, TX (US); Keith Allen Sauer, Spring, TX (US); Steven Dale Webster, Montgomery, TX (US)

(21) Appl. No.: 19/194,272

(22) Filed: Apr. 30, 2025

(51) Int. Cl. H05K 7/20; F28F 9/02; G06F 1/20

(52) U.S. Cl. CPC H05K 7/20236; G06F 1/20; F28F 9/02

(57) ABSTRACT

A heatsink for immersion cooling a processor of an information processing device includes a base, heat dissipating protrusions, and a manifold. The base has a first face to thermally couple to the processor. The heat dissipating protrusions, such as fins, are coupled to and protrude from a second face of the base. The manifold is attached directly to the second face of the base adjacent the heat dissipating protrusions. The manifold includes an inlet and multiple outlets. When the information processing device is immersed in an immersion cooling tank, the manifold receives via the inlet an input stream of the liquid coolant and expels output streams of the liquid coolant towards the heat dissipating protrusions via the outlets.

### INTRODUCTION

Information processing systems, such as servers and networking devices, are usually provided with cooling systems to remove heat and keep the components of the system within desired operation temperature ranges. Immersion cooling is one cooling approach which is gaining popularity as an alternative to traditional air-cooling systems and direct liquid cooling (DLC) systems. Immersion cooling involves submerging an information processing system in an electrically non-conductive (e.g., dielectric) liquid coolant, usually contained in a large tank which can hold multiple immersed systems concurrently. Unlike DLC where the liquid is contained within a closed loop and is not exposed directly to electrical components of the system, in immersion cooling the liquid coolant spreads throughout the system and directly contacts all the exposed components thereof. The liquid coolant can thus absorb heat from essentially all of the components of the system. The absorbed heat is then moved out of the individual system via convection of the liquid through the tank. A cooler, such as a heat exchanger, may be provided at the tank level to remove the heat from the liquid.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operations. In the drawings:

FIG. 1 is a schematic diagram illustrating an immersion cooling system, information processing device, and immersion heatsink.

FIG. 2 is a perspective view of an example immersion heatsink.

FIG. 3 is an exploded perspective view of the immersion heatsink of FIG. 2.

FIG. 4 is another exploded perspective view of the immersion heatsink of FIG. 2.

FIG. 5 is a top view of the immersion heatsink of FIG. 2.

FIG. 6 is a side view of the immersion heatsink of FIG. 2.

FIG. 7 is a front view of the immersion heatsink of FIG. 2.

FIG. 8 is an exploded perspective view of another example immersion heatsink.

FIG. 9 is a perspective view of the immersion heatsink of FIG. 8.

FIG. 10 is another perspective view of the immersion heatsink of FIG. 8.

### DETAILED DESCRIPTION

Immersion cooling is gaining popularity as an alternative to air cooling and DLC for a number of reasons. For example, processors (e.g., central processing units (CPUs), graphics processing units (GPU), etc.) and other components are increasing in heat generation, which is making it increasingly difficult to efficiently cool systems via airflow. In some high-power systems, it might not be possible for fans to adequately dissipate the amount of heat being generated. In other systems, it is possible for the fans to dissipate the heat but doing so may require the fans to run at high speed, which increases their power consumption and noise generation, making the cooling inefficient. In contrast, immersion cooling tanks generally include far fewer actively driven (powered) cooling elements, and thus they can provide cooling with substantially less power consumption and less noise generation.

For example, the powered cooling components of some immersion cooling tanks may be limited to just one or a few pumps, which may, for example, drive some bulk circulation of the liquid through the tank and through the cooler of the tank. A single tank may hold multiple servers, in some instances as many as could be held by a conventional rack (e.g., around twenty 2U-servers, in some cases). Thus, in some cases, only a few powered cooling components are needed to provide cooling for many servers. In contrast, an air-cooled rack with a comparable number of servers as the tank may require multiple dozens of fans—for example, assuming the rack has about twenty 2U-servers, over a hundred fans may be present. Thus, the immersion cooling tank will draw much less power, and generate much less noise, than the comparable air-cooled rack.

In addition, DLC generally requires a sophisticated closed cooling loop to be provided to circulate liquid coolant through the information processing systems, with the cooling loop comprising tubes, valves, pumps, cold plates, leak detection devices, and many other pieces of liquid cooling infrastructure. In the case of a rack with multiple servers, the overall liquid cooling loop for the rack may include multiple sub-loops, one for each individual system in the rack. Thus, DLC solutions tend to be very expensive and complicated to implement, and accordingly DLC has usually been reserved for high-power and high-cost systems, such as high-performance compute (HPC) systems (aka supercomputers), where the cost can be justified. Often, DLC is used for cooling the highest power components, such as CPUs. This in itself can be costly. Furthermore, in some systems DLC is also used for cooling the myriad other components that are dispersed throughout the system. This greatly increases the costs and complexity of the cooling solution, as every component may need to be thermally coupled to the liquid cooling loop and there are many components with irregular shapes, disparate locations, and varying cooling needs. To reduce some of the cost and complexity, some systems will use DLC to cool just high-powered components (e.g., CPUs) and will include air cooling to cool the other ancillary components. While this hybrid approach can be effective, the DLC components can still be costly and complicated (albeit less so than in a DLC-only system) and the air-cooling components suffer from the same drawbacks as air-cooled system (high power consumption and noise generation).

In contrast, immersion cooling generally does not require the large and complicated custom liquid cooling loops and associated infrastructure often needed for DLC, which can make immersion cooling less costly and complicated to implement in the long run. In addition, because immersion cooling allows the coolant to spread throughout the system and contact all exposed components, no special effort or cost is required to ensure that the non-CPU components receive cooling along with the CPUs.

However, while immersion cooling can be effective at cooling many systems, in some cases, immersion cooling tanks may sometimes provide less cooling than may be desired for certain high-power components with concentrated heat generation, such as some very hot processors. In particular, some processors can generate heat at a rate that exceeds the rate at which the surrounding liquid can absorb and carry the heat away via the natural convection present in the immersion tank, which results in the temperature of the processor rising and, eventually, performance of the processor being throttled to avoid overheating.

To address these issues, disclosed herein is a heatsink designed specifically for immersion cooling of an information processing device with a forced-convection manifold integrated therein (“immersion heatsink”). This immersion heatsink may be configured to cool a processor of the information processing device, such as a CPU, a GPU, a system-on-chip (SoC), an application specific integrated circuit (ASIC), or other processor. The immersion heatsink includes a thermally conductive base with a first face that thermally couples with the processor to absorb heat therefrom. A set of thermally conductive heat dissipating protrusions (e.g., fins) are thermally coupled to the base, with the protrusions protruding away from a second face of the base. When the information processing device is immersed in a pool of liquid coolant, the second face and the set of protrusions are exposed to the liquid coolant and transfer heat absorbed by the base into the liquid coolant, thus cooling the processor. The second face and the protrusions together have an exposed surface area in contact with the surrounding liquid that greatly exceeds that of the processor alone, and this allows the immersion heatsink to conduct heat into the liquid much more rapidly than would be possible with the processor alone. In addition, the immersion heatsink includes a manifold which is integrated therein. The manifold is attached to the base, which receives an inflow of liquid coolant drawn from the surrounding pool of liquid (by a pump) and which expels multiple output streams of the liquid coolant from a series of outlets, which are arranged to direct the output streams towards the protrusions (e.g., fins). These streams of coolant create forced convection through the immersion heatsink which reduces thermal resistance and increases the rate at which heat is transferred from the protrusions and the second face into the liquid. Thus, the immersion heatsink allows for the temperature of the processor to be greatly reduced as compared to if the processor were passively cooled in the immersion fluid. This can allow for a given processor to be run more efficiently, or for a more powerful processor to be utilized while retaining a given efficiency.

The immersion heatsinks disclosed herein may provide performance superior to what could be achieved using a heatsink designed for air cooling in an immersion cooling system (“air heatsink”). While an air heatsink might work in an immersion cooling context, it may not be well optimized for immersion cooling. For example, many air heatsinks have a very fine fin pitch (i.e., a small spacing between each fin), which works well in air cooling but which may result in suboptimal results in immersion cooling. For example, the liquid coolant may have a higher viscosity than air and thus may not flow very freely through the air heatsink. The immersion heatsinks disclosed herein, in contrast, may have heat dissipating protrusions designed to work well in immersion cooling, which may include, in some examples, fins having a coarser fin pitch than the fins of some air heatsinks, allowing for better flow of the liquid through the fins and thus better cooling performance. In addition, the manifold integrated into the immersion heatsink provides force convection of liquid through the protrusions, which may greatly increase the thermal performance of the heatsink as compared to air heatsinks which would lack such convection.

In some examples, a system which was originally designed for air cooling may be retrofitted or converted for immersion cooling by, among other things, removing an air heatsink therefrom and replacing it with one of the immersion heatsinks disclosed herein. In some examples, the base of the immersion heatsink may include mounting features which are compatible with heatsink mounting features of a system board which were originally designed for mounting an air heatsink. Thus, additional mounting features do not need to be added to an existing system or designed into a new system to accommodate the immersion heatsink.

Moreover, because the manifold is integrated into the immersion heatsink (i.e., attached to the base), the manifold is automatically installed in a system as part of installing the immersion heatsink, with the manifold residing within the space reserved for a heatsink. In contrast, if a separate heatsink and manifold are used, then multiple installation processes may be needed (one for the heatsink, one for the manifold), complicating the installation. In addition, the manifold may sit outside the space reserved for a heatsink, and thus some additional space may need to be provided for the manifold, which may not be feasible in some space-constrained systems. Separate mounting features to secure the manifold to a chassis may also be needed, which some existing systems may lack and which may drive up costs in designing new systems.

Furthermore, with the manifold integrated into the immersion heatsink, the position of the manifold relative to the protrusions is precisely controlled. This ensures that the output streams are directed to flow through the protrusions precisely as desired by the heatsink designer. In contrast, if separate heatsink and manifold are used, it can be more challenging to control the manifold position with precision—errors in installation, tolerances, or various other factors may result in there being some variability in manifold positioning relative to the heatsink. This can result in the output streams not being optimal relative to the protrusions, which may reduce cooling performance.

Turning now to the figures, various devices, systems, and methods in accordance with nonlimiting aspects of the present disclosure will be described.

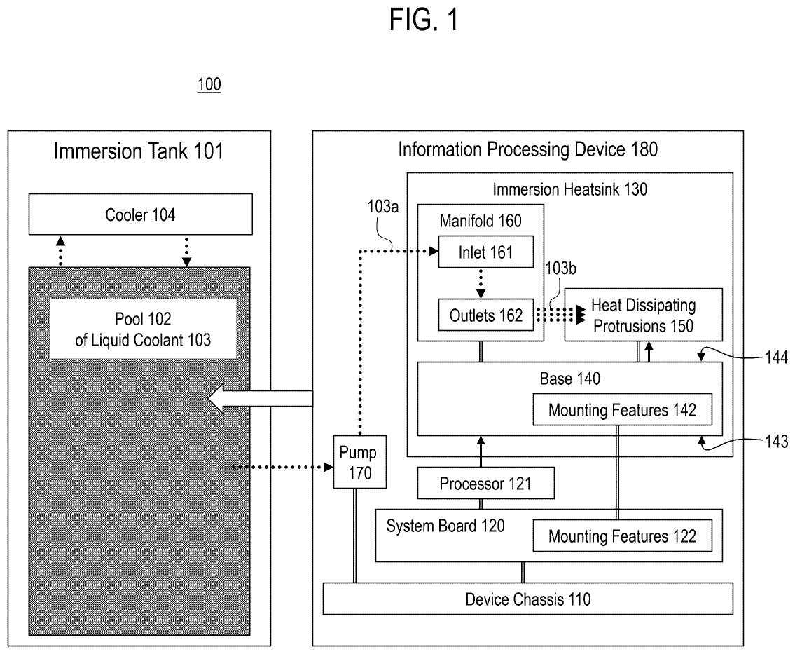

FIG. 1 is a schematic diagram conceptually illustrating a system 100, which includes an immersion cooling tank 101 and an information processing device 180 with an immersion heatsink 130. FIG. 1 is schematic and conceptual in nature and is not intended to illustrate spatial relationships, shapes, dimensions, or other structural details unless otherwise mentioned. Moreover, FIG. 1 is not intended to exhaustively depict all aspects of the system 100, information processing device 180, or immersion heatsink 130. Elements illustrated in FIG. 1 may be included in numbers and/or arrangements that differ from the illustrated numbers or arrangements, some examples may include elements that are not illustrated in FIG. 1, and/or some examples may omit one or more of the elements that are illustrated in FIG. 1. FIG. 1 illustrates the full system 100 to aid understanding, but some examples disclosed herein may comprise just the information processing device 180 with the heatsink 130 installed (but without immersion tank 101), while still other examples may comprise just the heatsink 130 by itself.

In FIG. 1, physical attachment/coupling between components is illustrated by double solid lines extending between the boxes depicting the components. Thermal coupling, e.g., contact, between components is illustrated by single solid lines extending between the boxes depicting the components, with the arrow indicating a direction of heat flow during normal usage. Liquid flow paths and fluidic connections between two components are depicted using dotted-line arrows extending between the boxes depicting the components, with the arrow indicating a direction of the flow.

As shown in FIG. 1, the system comprises an immersion tank 101 (“tank 101”). The immersion tank 101 comprises a tub or container or similar structure configured to provide immersion cooling to information processing devices such as the device 180. The tank 101 contains a pool 102 of liquid coolant 103 (“liquid 103”) that is electrically non-conducting (e.g., a dielectric). The tank 101 is configured to receive one or more information processing devices (e.g., servers), including the information processing device 180 (“device 180”) immersed in the pool 102. In this context, “immersed” means that at least a system board of the information processing device 180 is submerged in the pool 102. In some examples, the entirety of each information processing device 180 may be fully submerged. In other examples, a small portion of a device 180, such as a support bracket which supports the system, may protrude out of the pool 102. The immersion of the device 180 in the pool 102 is indicated schematically in FIG. 1 by the white arrow.

The immersion tank 101 may also include a cooler 104 configured to cool the liquid 103. For example, the cooler 104 may include a heat exchanger that cools the liquid 103 by heat exchange with facility cooling fluid of a facility cooling system. The heat exchanger of the cooler 104 may be, for example, a liquid-to-liquid heat exchanger, in which case the facility cooling fluid may be a liquid which runs in a facility liquid loop through the facility to cool one or more immersion tanks including tank 101. In some examples, the cooler 104 is disposed outside the pool 102, in which case the cooler may receive a flow of the liquid 103 from the pool 102, cool that flow of liquid 103 by heat exchange with the facility cooling fluid, and then return the now-cooled flow of liquid 103 back to the pool 102. A tank pump may be disposed in the tank 101 to facilitate this flow of liquid 103, which may also promote (or amplify) a bulk movement of liquid through the tank 101. In other examples, the cooler 104 may be immersed in the pool 102 to directly cool the surrounding liquid coolant 103.

The information processing device 180 may comprise a server, networking device, or other device configured to process digital information. The device 180 comprises a system board 120 (e.g., motherboard) to which a processor 121 is mounted. The processor 121 may comprise (or may be a part of) a CPU, a GPU, an SoC, an ASIC, or any other processor. The system board 120 may also include other electronic components (not illustrated), including one or more additional processors, memory modules, etc. The system board 120 also includes mounting features 122 arranged around the processor 121 and configured to mount a heatsink, such as immersion heatsink 130, as will be described in more detail below.

The device 180 may also comprise a chassis 110, which supports the system board 120. In some examples, the chassis 110 houses (encloses) the system board 120 and other components of the device 180, while in other examples the chassis 110 merely supports the system board 120 without housing it (for example, the chassis 110 may have a tray configuration). In other examples, the chassis 110 may be omitted. As previously mentioned, FIG. 1 is schematic in nature, and thus does not show the structural details of the chassis 110 or system board 120 or their positional relationships to one another or to the other components.

The immersion heatsink 130 (“heatsink 130”) is configured to cool processor 121 when installed in the information processing device 180. FIG. 1 shows the heatsink 130 as part of the device 180 in an installed state. In other examples, the heatsink 130 is by itself, i.e., in an uninstalled state and not yet part of device 180. The immersion heatsink 130 comprises a base 140, a manifold 160, and mounting features 142.

The base 140 comprises a thermally conductive body with a generally plate-like shape, meaning that the body has two broad and generally planar faces, which are disposed opposite from and parallel to one another, and a number of narrow edge surfaces extending between and connecting the two broad planar faces. Moreover, the width and length dimensions of this body, which are parallel to the broad faces thereof, both greatly exceed (e.g., 5 or more times larger than) a thickness dimension of the body, which is perpendicular to the broad faces thereof. In some examples, the base 140 is formed from a plate of thermally conductive metal, such as aluminum, copper, steel, etc. In some examples, the base 140 comprises a vapor chamber, which includes a sealed internal volume inside the base in which a working fluid is contained and configured to transfer heat between the broad faces of the base 140 through a phase change cycle of the working fluid.

The two broad faces of the plate-like body of the base 140 include a first face 143 and a second face 144. In an installed state, the first face 143 is thermally coupled with (e.g., placed in contact with) the processor 121, such that heat generated by the processor 121 is transferred via conduction into the base 140, as indicated in FIG. 1 by a solid line arrow. The heat is then transferred from the first face 143 through the thickness of the base 140 to the second face 144. In examples where the base 140 comprises a plate of solid metal, the heat is transferred through the thickness of the base 140 via conduction. In examples where the base 140 comprises a vapor chamber, the heat is transferred through the thickness of the base 140 via conduction and a vapor change heat transport cycle.

The heatsink 130 further comprises a set of heat dissipating protrusions 150 (“protrusions 150”). These protrusions 150 each comprise a body of thermally conductive metal, such as aluminum, copper, etc., which is physically attached (directly or indirectly) to the base 140 with the protrusion 150 protruding from the second face 144 in a direction perpendicular to the second face 144 and away from the first face 143, or in other words along a height dimension of the heatsink 130. The protrusions 150 are also thermally coupled to the base 140, and thus the heat absorbed by the base 140 from the processor 121 transfers by conduction from the base 140 into the protrusions 150.

The protrusions 150 are arranged in an array, wherein the array includes protrusion positions arranged in rows and columns, with the rows extending parallel to a width dimension of the heatsink 130 and the columns extending parallel to a length dimension of the heatsink 130. In some examples, the array of protrusions 150 is a one-dimensional array having just one row of protrusion positions. In other examples, the array of protrusions 150 may be a two-dimensional array having multiple rows of protrusion positions. In some examples, where the protrusions 150 are in a two-dimensional array, some rows are offset relative to other rows, meaning that each position within one row is not necessarily aligned with (e.g., in the same column as) the corresponding position in another row, and/or some columns are offset relative to other columns, that each position within one column is not necessarily aligned with (e.g., in the same row as) the corresponding position in another column. Note that references herein to a one-dimensional array and a two-dimensional array refer to the positions at which protrusions 150 are disposed, and not to the structure of the protrusions 150 themselves, which are three dimensional.

The protrusions 150 define channels therebetween which extend along a length dimension of the heatsink 130. These channels extend between adjacent columns of the protrusion 150. The channels form liquid flow paths through which liquid 103 can flow, allowing the liquid 103 to make contact with the protrusions 150 and absorb heat therefrom. Thus, heat absorbed from the processor 121 is dissipated by the protrusions 150 into the surrounding liquid 103.

In some examples, the heat dissipating protrusions 150 comprise fins, which are relatively thin and planar sheets or plates of thermally conductive metal, such as aluminum, copper, etc. In such examples, the fins are physically attached to the base 140 with the fins oriented perpendicular to the base 140 and parallel to one another. (As used herein, the orientation of a planar body, like the fins and the base 140, corresponds to the orientation of the broad faces of the planar body). These fins protrude from the second face 144 along the height dimension of the heatsink 130 and extend longitudinally along the length dimension of the heatsink 130, with each pair of adjacent fins defining one of the above-described channels therebetween. The fins may be arranged in a one-dimensional array, meaning that the fins are arranged at positions distributed across the width dimension of the heatsink 130. In other words, there may be one row of the fins, with each fin position corresponding to a different column of the one-dimensional array. Although the fin positions are distributed across the width dimension, the fins themselves may extend longitudinally along the length dimension. The fins may be formed together with a base (e.g., the base 140 or another base) by extrusion, skiving, casting, or other manufacturing processes. For instance, in some examples, the base and fins are parts of the same extruded metal body. Or the fins may be joined with a base, such as by welding, brazing, etc.

In some examples, the heat dissipating protrusions 150 comprise pins or pin-fins. Pins comprise columnar protrusions, such as cylinders, square columns, or any other sort of columns. These pins may be arranged in a two-dimensional array, for example with multiple rows and columns of pins. Pin-fins comprise protrusions which are generally planar in nature, similar to fins, but which are relatively short along a length dimension thereof as compared to standard fins. For example, whereas regular fins usually have a length that exceeds their height (referring to the direction of protrusion from a base), a pin-fin may have a length that is less than its height. Furthermore, whereas regular fins are usually arrayed relative to one another along one dimension (e.g., one row of multiple parallel fins), pins or pin-fins may be arranged in a two-dimensional array (e.g., multiple rows and columns of pins or pin-fins). In some examples, pins or pin-fins may be arranged to have a coarser pitch along one or more dimensions (e.g., greater spacing between rows and/or columns of pins or pin-fins) than the pins or pin-fins of some air heatsinks, allowing for better flow of the liquid and thus better cooling performance.

In some examples, the protrusions 150 are attached directly to the second face 144. For instance, in some examples the base 140 and the protrusions 150 are all integrally formed together as part of the same monolithic body. For example, such a monolithic body could be formed by extrusion or machining from the same monolithic piece of material, by casting or 3D printing together as a unitary part, or by other manufacturing techniques. In other examples, the protrusions 150 and/or the base 140 may include one or more parts that are initially formed separately and then are later joined together, such as by brazing, welding, or other fastening/joining techniques.

In some examples, the base 140 comprises two (or more) parts that are initially separate and which are later joined together to form base 140. In some of these examples, the protrusions 150 are attached to one of these parts. For example, in some examples, an insert assembly may be formed which comprises an insert base and the protrusions 150, with the insert base being a first part of the base 140 and with the protrusions 150 being attached to the insert base. The insert base may be a plate-like structure. The protrusions 150 may be integrally formed with the insert base, or they may be formed separately from and then later joined to the insert base. The insert base (the first part of the base 140) may then be joined to a second part of the base 140 by brazing, welding, adhesives, mechanical fasteners, friction fit, or other fastening/joining techniques, thus completing formation of the base 140. The second part of the base 140 may, for example, define an outer perimeter of the base 140 and may include the mounting features 142 therein and may have the manifold 160 (described below) attached thereto, whereas the first part of the base 140 may occupy a more central region of the base 140 and carries the protrusions 150. For example, the second part of the base 140 may have a central socket, recessed from the second face 144, into which the first part of the base 140 (i.e., the insert base) is inserted. In some examples, this central socket may extend partway through the thickness of the second part of the base 140, while in other examples, this central socket may extend all the way through the thickness of the second part of the base 140. In some examples, the first face 143 may be formed entirely by the second part of the base 140, while in other examples the first face 143 may be formed in part by the first part of the base 140 (e.g., by the bottom face of the insert base of the insert assembly). In some examples, the first part of the base 140 (the insert base) and the second part of the base 140 may be formed from the same material, while in other examples, they may be formed from different materials.

Having multiple separately formed parts of the base 140 may facilitate the formation of the heatsink 130 from multiple different materials, which can allow for a desired balance between strength, thermal performance, cost, and other factors to be achieved. For instance, copper could be used for the insert assembly to take advantage of its high thermal conductivity, while aluminum could be used for the second part of the base 140 to take advantage of its lower cost and high strength. Of course, this is just one example, and any desired combination of materials could be selected, each of which may provide its own advantages and/or drawbacks in various circumstances. In addition, even if the same materials are used, it may be easier, faster, or otherwise more convenient to form insert assembly separately from the second part of the base 140, for example due to different manufacturing processes being used to form these parts.

The manifold 160 comprises a hollow manifold body which has an interior chamber (e.g., a bore or empty volume contained within the body), an inlet 161 fluidically coupling the interior chamber to an external environment, and a plurality of outlets 162 fluidically coupling the interior chamber to the external environment. Thus, the manifold 160 is configured to allow an input stream 103a of the liquid 103 to flow into the interior chamber via the inlet 161 and then to output that liquid 103 from the interior chamber back into the external environment as a plurality of output streams 103b via the outlets 162. The manifold body extends along a width dimension of the heatsink 130, adjacent one end of the set of protrusions 150, and the outlets 162 are distributed across this width dimension such that each outlet 162 faces a different subset of the protrusions 150 and/or subset of the channels defined between the protrusions 150. The number and locations of outlets 162 may vary from one implementation to another. In some examples, some protrusions 150 and/or channels do not have an outlet 162 opposite therefrom.

The inlet 132 may include an opening in the manifold body that fluidically connects the inlet 132 to the interior chamber. The inlet 132 may further include a liquid coupling or liquid fitting configured to couple with a liquid conduit 141 (e.g., a hose, a pipe, a tube, or any other liquid conduit). Thus, the inlet 132 may include coupling features to facilitate this coupling. Examples of such liquid couplings/fittings include hose barbs, threaded fittings, compression fittings, quick disconnects (QD), and other liquid couplings/fittings. Examples of the coupling features of these fittings may include barbs, threads, gaskets, quick disconnect features (springs, poppets, etc.), etc. The outlets 162 may include openings through the manifold body that fluidically connect the outlets 162 to the interior chamber. The outlets 162 may further include nozzles configured to focus the output streams 103b to increase their velocity and/or decrease their dispersion (i.e., make them more columnar).

The outlets 162 are positioned such that the outlet streams 103b are directed towards the protrusions 150. More specifically, in some examples, the outlets 162 direct the outlet streams 103b to flow into and through channels between adjacent columns of protrusions 150 (e.g., through channels between adjacent fins). In some examples, some channels do not have an outlet stream 103b directed to flow therethrough, but at least some of the channels do receive such an outlet stream 103b. The forced convection of the liquid 103 around the protrusions 150 created by these outlet streams 103b flowing through the channels reduces thermal resistance and increases the rate of heat transfer into the liquid 103.

Some of the heat absorbed by the base 140 transfers into the protrusions 150 from which it is dissipated into the liquid 103, but some of the heat absorbed by the base 140 may transfer from base 140 into the liquid 103 without flowing into a protrusion 150. In some examples, the outlet streams 103b also help to increase the rate at which such heat is transferred from the base 140 directly into liquid 103. In some examples, some (or all) of the outlet streams are angled slightly towards the base 140 such that the outlet streams 103b flow both longitudinally (through the channels) and also towards the base 140. Thus, a portion of the outlet stream 103b may contact or flow adjacent to the base 140, which can help facilitate faster transfer of heat directly from the base 140 into the liquid 103.

The manifold 160 is attached to the second face 144 of the base 140. In some examples, at least part of the manifold 160 is integrally connected to the base 140, meaning they are formed as parts of the same unitary (monolithic) body. For example, a portion of manifold 160 and the base 140 may be cast together in the same casting, formed together in an additive manufacturing process (e.g., 3D printing), etc. In other examples, the manifold 160 may be formed as a separate piece which is attached to the base 140, for example via fasteners, heat staking, adhesives, welding, brazing, or other fastening mechanisms. The manifold 160 is attached to the base 140 in a manner that aligns the outlets 162 relative to the base 140 such that the output streams 103b are directed as described above.

In some examples, the manifold 160 is formed as two (or more) parts which are coupled together. This may allow for easier manufacturing. For example, the internal chamber inside the manifold body and other internal features may be difficult to manufacture if the manifold 160 were produced as a monolithic part, but may be quite easily produced if the manifold 160 is produced as two separate parts joined together. In some examples, the parts may include a bottom part which is attached to the second face 144 of the base 140 and a top part which is coupled to the bottom part, with the internal chamber of the manifold being defined in part by walls of the bottom part and in part by walls of the top part. In other words, in these examples, a seam or joining surface where the top and bottom parts join may split the internal chamber in two. This can make manufacturing of internal features of this chamber easier, as these features become external when formed in one of the parts, and only become internal to the manifold once the parts are joined together. In some examples, the manifold 160 may be metal and the parts thereof may be cast, 3D printed, or manufactured using some other suitable technique. In some examples, the manifold may be plastic and the parts thereof may be injection molded, 3D printed, or manufactured using some other suitable technique. In some examples, the parts of the manifold 160 are joined together by fasteners, such as screws. In some examples, the same fasteners which couple the parts of the manifold 160 together may also couple the manifold 160 to the base 140.

The base 140 may further include mounting features 142 which are configured to mount the base 140 to the system board 120 and/or chassis 110. These mounting features 142 may include, in some examples, holes arranged to receive fasteners, such as screws. As another example, the mounting features 142 may include a latching mechanism which is formed into, or attached to, the base, such as a half-turn or quarter-turn latch or any other desired latch. As another example, the mounting features 142 may include features configured to receive or engage with retainers (e.g., spring clips) which are attached to the system board 120 and which can be moved into engagement with the base 140. In some examples, the mounting features 142 are configured to engage with mounting features 122 of the system board 120. For example, if the mounting features 142 include holes to receive fasteners, then the mounting features 122 may comprise holes in corresponding positions and configured to receive the same fasteners. As another example, if the mounting features 142 include latches, the mounting features 122 may include latch receptacles or complementary latch elements configured to engage with the latches.

In some examples, the mounting features 122 may be the same mounting features which are used for mounting an air-cooled heat sink to the processor 121. In such examples, the mounting features 142 of the immersion heatsink 130 may be configured to mount to these same mounting features 122 in lieu of the air-cooled heatsink. In other words, the mounting features 142 of the immersion heatsink 130 may have locations and attachment mechanisms that mimic those of an air-cooled heat sink. This can be useful in some circumstances where it is desired to convert a system which was originally designed for air cooling into a state in which it can be used in immersion cooling. For example, to convert the system, the fans, air-cooled heatsink, airflow baffles, and other air-cooling paraphernalia that may have been part of the system may be removed, and in their place the immersion heatsink 130 may be added.

The device 180 may also comprise a pump 170 and liquid conduits (not illustrated), which are configured to supply the input stream 103a of liquid coolant 103 to the manifold 160. The pump 170 is configured to draw some of the liquid coolant 103 from the pool 102 and force the liquid 103 to flow into and through the manifold 160, thereby generating the output streams 103b ejected out of the outlets 162 towards the protrusions 150, as shown by the dash-lined arrows in FIG. 1. Specifically, pump 170 may be coupled to the inlet 161, either directly or via one or more liquid conduits. Although not illustrated in FIG. 1, the output streams 103b ejected from the outlets 162 return into the pool 102. The pump 170 may be powered by the same power source (not illustrated) which powers the system board 120, such as a power supply unit.

In other examples, the pump 170 may be omitted form the device 180, and instead a pump may be provided separate from the device 180 to circulate liquid. For example, the immersion cooling tank may have one or more tank pumps to circulate liquid through the tank, and one of these tank pumps may be fluidically coupled with the manifold 160 to supply the input stream 103a thereto.

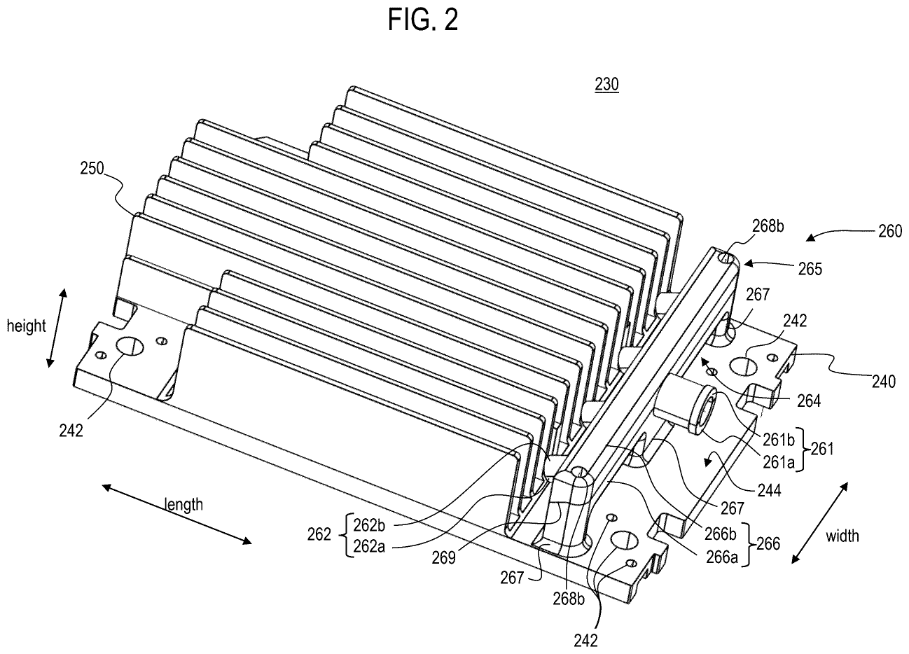

Turning now to FIGS. 2-7, an example immersion heatsink 230 will be described. The immersion heatsink 230 is an example implementation of the immersion heatsink 130 described above. Thus, some components of the immersion heatsink 230 are similar to (e.g., example implementations or configuration of) corresponding components already described above, and thus the descriptions of the components of the immersion heatsink 130 above are applicable to the similar components of the immersion heatsink 230, and duplicative descriptions of certain aspects of the immersion heatsink 230 may thus be omitted. Corresponding components may be referred to using reference numbers having the same last two digits, such as 150 and 250. It should be understood that the immersion heatsink 230 is but one possible implementation of the immersion heatsink 130, and the immersion heatsink 130 is not limited to the immersion heatsink 230. Similarly, the individual components of the immersion heatsink 230 are examples of the corresponding individual components of the immersion heatsink 130, but the individual components of the immersion heatsink 130 are not limited to the corresponding components of the immersion heatsink 230.

The order in which components of the immersion heatsink 230 are described below is chosen to aid in understanding the structural and functional relationships between the components. However, the logical order which best aids this understanding is not necessarily the same as the order in which the components appear in the drawings. Thus, FIGS. 2-7 will not be described in strict sequence below. Instead, as aspects of the immersion heatsink are described, certain figures that are thought to be most helpful to understanding the particular aspect under discussion will be called out, even if that requires moving back and forth between the drawings out of order.

As shown in FIGS. 2-7, the immersion heatsink 230 comprises a base 240, a manifold 260 coupled to the base 240, and fins 250 coupled to the base 240.

In this example, the base 240 comprises a metal (e.g., aluminum) plate with a first face 243 and a second face 244 opposite the first face 243. The first face 243 is configured to be thermally coupled with a processor of an information processing device, whereas the second face 244 is configured to be exposed to liquid coolant in a pool of an immersion cooling tank when the information processing device is immersed therein. In some examples, a thermal interface material (TIM) may be disposed on the first face 243. The TIM may be, for example, a graphite pad/mesh, a malleable metal foil (e.g., indium foil), a carbon nano-tube mesh, or any other TIM which is compatible with (e.g., which is not dissolved by or reactant with) the liquid coolant. When the base 240 is installed on a processor, the TIM (if present) sits between the first face 243 and the processor and is in mutual contact with both, such that the TIM thermally couples the first face 243 with the processor. In some examples, the TIM may be omitted, in which case the first face 243 may directly contact the processor.

The base 240 includes mounting features 242. In this example, there are four sets of the mounting features 242, one at each of the four corners of the base 240. In this example, each of these sets of mounting features 242 includes three mounting features 242 in the form of apertures through the base 240. These mounting features 242 may be configured to receive fasteners to fasten the base 240 to a system board. In some examples, the fasteners include screws, studs, bolts, etc. In other examples, the fasteners include latching devices mounted to the base 240. For example, each set of three mounting features 242 may receive one such latching device, with two of the mounting features of that set securing the latching device to the base 240 and the third mounting feature 242 of the set allowing engagement of the latching device with mounting features of the system board. The mounting features 242 may be configured to allow engagement with air-cooled heatsink mounting features of the system board, meaning mounting features on the system board to which an air-cooled heatsink would be mountable.

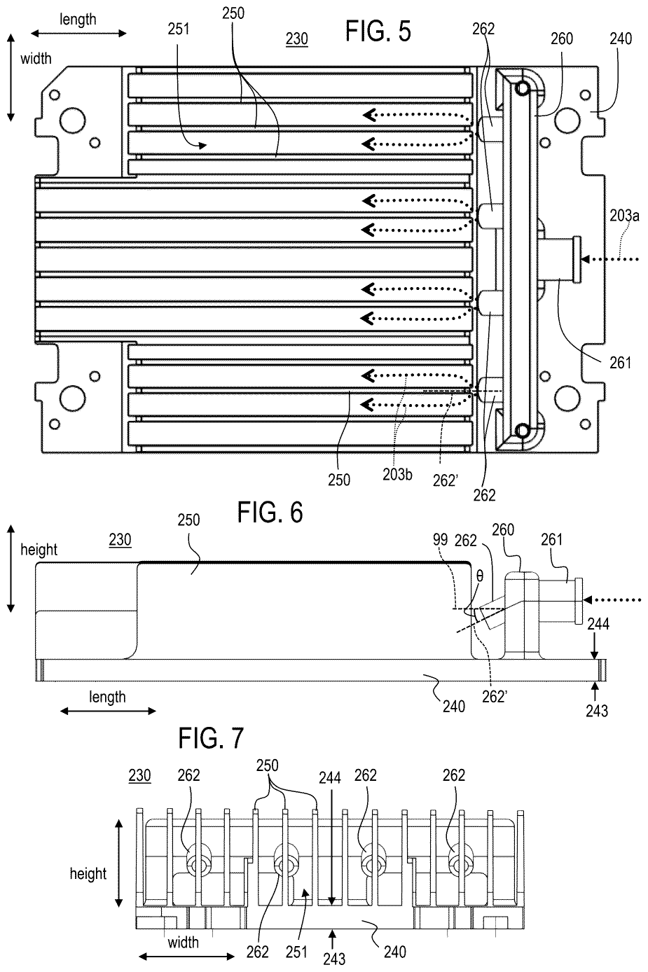

A set of multiple fins 250 are coupled to the base 240, as shown in FIG. 2 (only a few of the illustrated fins 250 are labeled). The fins 250 are one example implementation of the protrusions 150. The fins 250 are relatively thin and planar sheets or plates of thermally conductive metal, such as aluminum, copper, etc. The fins 250 are oriented perpendicular to the base 240 and parallel to one another. As shown in FIG. 2, the fins 250 protrude from the second face 244 along the height dimension of the heatsink 230 and extend along the length dimension of the heatsink 230. Each pair of adjacent fins 250 define a channel 251 therebetween, as shown in FIGS. 5 and 7 (only one of the channels 251 is labeled). The fins 250 may be arranged in a one-dimensional array with positions thereof distributed across the width dimension of the heatsink 230. Although the fin positions are distributed across the width dimension, the fins 250 themselves extend longitudinally along the length dimension, as shown. In this example, the fins 250 are integrally connected to the base 240, forming one monolithic body. For example, the base 240 and fins 250 may be integrally formed together by extrusion, skiving, casting, or other manufacturing processes. In some examples, the base 240 and the fins 250 are parts of the same monolith extruded metal body. In some examples, the fins 250 have a fin pitch that is coarser (i.e., wider inter-fin spacing) than the air-cooled fins of an air-cooled processor heatsink.

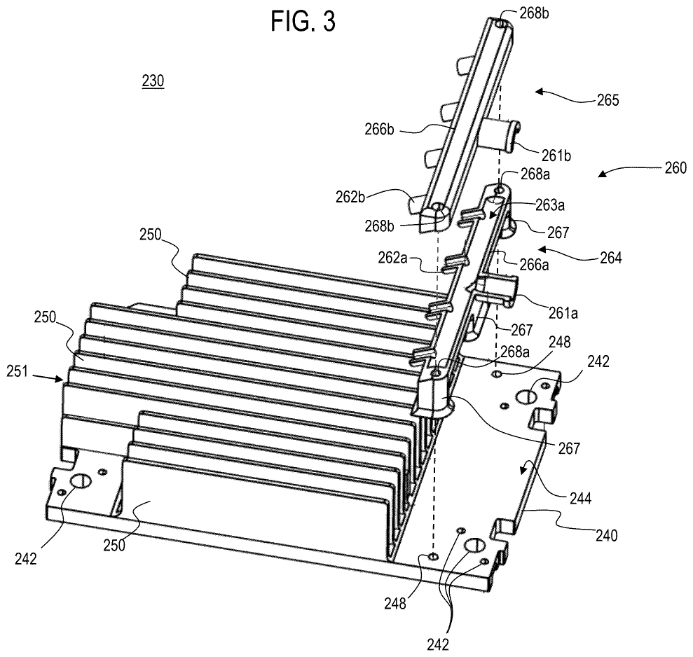

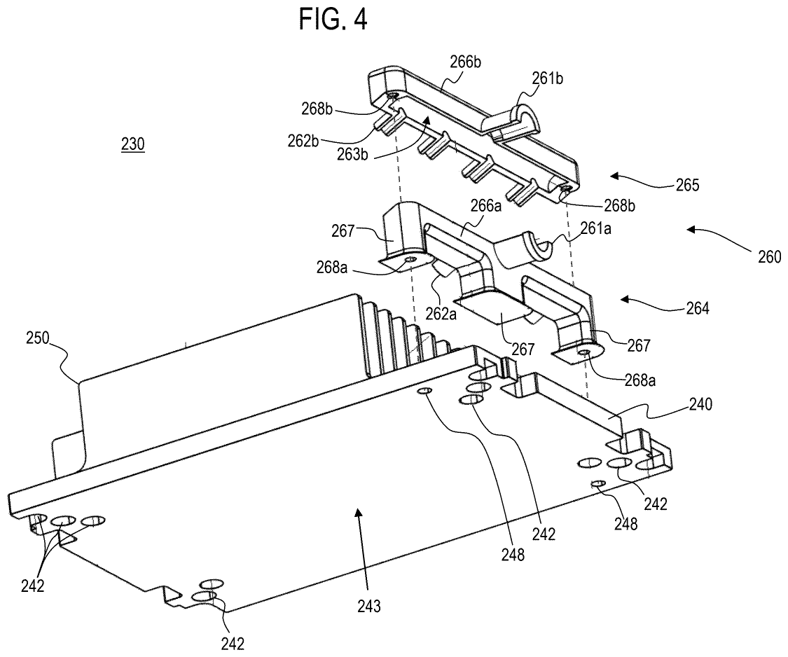

As shown in FIGS. 2-4, the manifold 260 comprises a manifold body 266 (“body 266”), supports 267 coupled to body 266, an inlet 261 coupled to the body 266, and four outlets 262 coupled to the body 266. As best seen in FIGS. 3-4, in this example the manifold body 266 is formed from two distinct parts—a bottom body part 266a and a top body part 266b. These two body parts 266a and 266b are joined together at seam 269, as shown in FIG. 2. The body 266 is hollow, with walls of the body 266 defining an interior chamber 263 inside the body 266. The bottom body part 266a defines a bottom half 263a of the chamber 263 (see FIG. 3) while the top body part 266b defines a top half 263b of the chamber 263 (see FIG. 4), such that when the two parts 266a and 266b are joined together, the bottom and top halves 263a and 263b join together and form chamber 263. This two-part construction of the body 266 makes it easier to form the interior chamber 263, as each half 263a and 263b thereof can be formed as an exterior feature on the respective body part 266a or 266b, rather than as an interior feature (in some cases, interior features may be harder to manufacture).

The supports 267 are coupled to the bottom body part 266a of the manifold body 266. In the illustrated example, the supports 267 are integrally formed with the bottom body part 266a, i.e., they are part of the same monolithic body. In other examples, the supports 267 may be distinct from and coupled to the bottom body part 266a.

As shown in FIGS. 3 and 4, the top body part 266b comprises holes 268b on opposite ends thereof to receive fasteners (e.g., screws). The bottom body part 266a also comprises holes 268a aligned with holes 268b and also configured to receive the same fasteners. The holes 268a also extend through two of the supports 267, as shown in FIG. 4, and are aligned with corresponding holes 248 in the base 240, as shown in FIG. 3, which are configured to receive the same fasteners. Thus, there are two sets of aligned holes (a hole 268a aligned with a hole 248, as well as a hole 268b aligned with the hole 248), with each set arranged to receive a fastener. The fasteners when inserted through these sets of aligned holes mechanically fasten the top body part 266b and bottom body part 266a together, thereby forming the manifold body 266, and simultaneously mechanically fastening the manifold 260 to the base 240. In some examples, the fasteners may include screws and the holes 248 may include threading to engage with threads of the screws.

As shown in FIGS. 3 and 4, the inlet 261 and the outlets 262 are fluidically coupled with the interior chamber 263 of the manifold 260. Specifically, the inlet 261 and the outlets 262 each comprise a first opening through a wall of the manifold body 266 to fluidically connect with the interior chamber 263. Moreover, the inlet 261 comprises a fluid coupling coupled to the manifold body over the first opening of the inlet 261. The outlets 262 further comprise nozzles coupled to the manifold body 266 over their respective first openings. The fluid coupling of the inlet 261 and the nozzles of the outlets 262 each define an internal channel which is fluidically coupled with the first opening of the respective inlet 261 or outlets 262. Thus, the internal chamber 263 fluidically connects the inlet 261 to each of outlets 262. Moreover, the internal channels of the inlet 261 and outlets 262 also comprise second openings which fluidically connect to the external environment. Thus, the inlet 261 and the outlets 262 fluidically couple the internal chamber 263 with the external environment. Accordingly, an input stream 203a of liquid from outside the manifold 260 (e.g., from a pump) can enter the manifold 260 by flowing into the interior channel of the inlet 261, flow from inlet 261 into the chamber 263, flow through the chamber 263, flow from the chamber 263 into the internal channels of the outlets 262, and then be ejected from the outlets 262 as the plural output streams 203b.

In the illustrated example, the inlet 261 and the outlets 262 are integrally formed with the body 266, such as via additive manufacturing, casting/molding, etc. More specifically, the inlet 261 is formed from two parts that are joined together, namely a bottom inlet part 261a and a top inlet part 261b. The bottom inlet part 261a is integrally formed with the bottom body part 266a, and top inlet part 261b is integrally formed with the top body part 266b, as shown in FIGS. 3 and 4. In this example, the fluid coupling portion of the inlet 261 has the form of a hose clamp fitting configured to couple with a hose, which may in turn be coupled to a pump which pumps the liquid coolant from an immersion tank into the manifold 260. In other examples, the fluid coupling portion of the inlet 261 could be replaced with any other desired fluid coupling, such as a threaded coupling, quick-disconnect fluid coupling, or others.

The outlets 262 are also each formed from two parts that are joined together, namely a bottom outlet part 262a and a top outlet part 262b. The bottom outlet part 262a is integrally formed with the bottom body part 266a, and top outlet part 262b is integrally formed with the top body part 266b, as shown in FIGS. 3 and 4. Each outlet 262 comprises an opening through a wall of the manifold body 266 and an internal conduit fluidically coupled with that opening, such that the internal chamber 263 of the manifold body 266 is fluidically coupled with an external environment via the outlet 262.

The outlets 262 are disposed adjacent one side of the fins 250 and distributed across the width dimension of the heatsink 230, as shown in FIG. 5. In this example, the outlets 262 include nozzles that point at an angle towards the fins 250 and the base 240. More specifically, as shown in FIGS. 5 and 6, a central axis 262′ of each outlet 262 extends in a direction that is parallel to the fins 250 and at an acute angle θ relative to a horizontal plane 99 parallel to the second face 244 of base 240. Thus, as the streams 203b flow through the channels 251 between the fins 250, a portion of each output stream 203b may impinge upon the face 244 of base 240, which may redirect the stream so that it may flow generally parallel to the face 244 thereafter. Thus, the output streams 203b may contact both the fins 250 and the face 244, thus absorbing heat directly from both. In addition, the output streams 203b may cause circulation of other surrounding liquid, for example by entraining liquid to flow along with the streams 203b. Other liquid may also flow around the fins 250 and through the channels 251 independently of the output streams 203b, for example due to natural convection and/or a bulk movement of liquid through the system due to a tank or system level pump. However, the forced convection provided by the output streams 203b may provide much greater cooling than the natural convection or bulk movement of liquid alone would. In some examples, θ is about 25°. In some examples, θ is between 0°and 30°. In some examples, θ is between 30°and 60°.

In the illustrated example, each outlet 262 is centered on a corresponding one of the fins 250, as shown in FIGS. 5 and 7. Thus, the output stream 203b output by a given outlet 262 is divided by the corresponding fin 250 into two streams 203b which flow along the two channels 251 adjacent to the corresponding fin 250, as shown in FIG. 5. In the illustrated example, not every channel 251 receives an output stream 203b from an outlet 262.

The number and type of outlets 262 can vary from one example to another depending on the needs of the particular system for which the heatsink 230 is designed. In some examples, different versions of manifold 260 having different numbers and/or types of outlets 262 may be produced, and each may be capable of mounting to the base 240 using the mounting arrangement described above, which can allow a system designer to customize the heatsink 230 as needed by selecting the manifold 260 most appropriate to the system.

In the illustrated example, there is equidistant spacing between the outlets 262 along the width dimension, but in other examples, the spacing between outlets 262 is not necessarily equidistant. In the illustrated example, there is one row of outlets 262 extending along the width dimension with all the outlets 262 having a similar height (along the height dimension) above the face 244, but in other examples, one or more outlets 262 may be disposed at different heights above the face 244 than one or more other outlets 262. In the illustrated example, all of the outlets 262 expel liquid at the same angle θ relative to the horizontal plane 99, but in other examples one or more outlets 262 may expel liquid at an angle different from one or more other outlets 262. For example, in one implementation a first set of outlets 262 may expel liquid at a first angle θ₁ while a second set of outlets 262 may expel liquid at a second angle θ₂ wherein θ₂<θ₁, such that the central axis of the liquid stream ejected from the first set of outlets 262 intersects with a closer portion of the face 224 while the central axis of the liquid stream ejected from the second set of outlets 262 intersects with a farther portion of the face 224. In the illustrated example, all of the outlets 262 have the same shape and configuration as one another, including having the same size and same shape output openings, and therefore all of the ejected streams of liquid have substantially similar characteristics (e.g., the same stream width, the same flow speed, etc.). In other examples, one or more outlets 262 may have a different shape or configuration than one or more other outlets 262 and thus their respective ejected streams may differ from one another in one or more characteristics. For example, a first set of outlets 262 may have larger output openings than a second set of outlets 262, resulting in the streams ejected by the first set of outlets 262 having larger diameter and being slower and the streams ejected by the second set of outlets 262 having smaller diameter and being faster. In the illustrated example, the openings of the outlet 262 are circular in cross-section, thus each outlet 262 generates a single stream which is essentially circular in cross-section. In other examples, the openings may have other cross-sectional shapes, such as an ellipse, a rectangle (slot), etc., which may produce different shapes of output streams. Furthermore, in some examples more than one opening may be provided per outlet 262, which may allow for multiple smaller output streams to be generated by a single outlet 262.

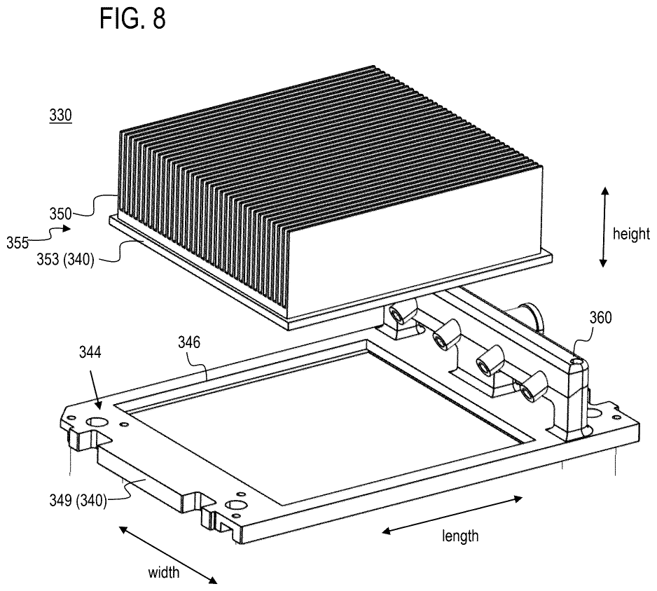

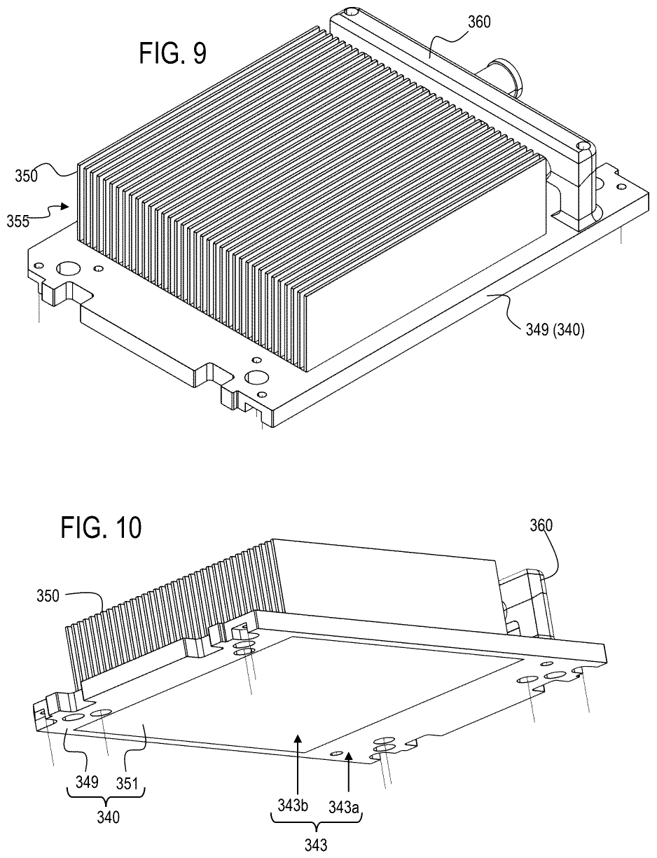

Turning to FIGS. 8-10, another example immersion heatsink 330 will be described. The immersion heatsink 330 is an example implementation of the immersion heatsink 130 described above. Thus, some components of the immersion heatsink 330 are similar to (e.g., example implementations or configuration of) corresponding components already described above, and thus the descriptions of the components of the immersion heatsink 130 above are applicable to the similar components of the immersion heatsink 330, and duplicative descriptions of certain aspects of the immersion heatsink 330 may thus be omitted. Corresponding components may be referred to using reference numbers having the same last two digits, such as 150 and 350. It should be understood that the immersion heatsink 330 is but one possible implementation of the immersion heatsink 130, and the immersion heatsink 130 is not limited to the immersion heatsink 330. Similarly, the individual components of the immersion heatsink 330 are examples of the corresponding individual components of the immersion heatsink 130, but the individual components of the immersion heatsink 130 are not limited to the corresponding components of the immersion heatsink 330.

The immersion heatsink 330 includes a base 340, fins 350, and a manifold 360.

The heatsink 330 differs from the heatsink 230 described above at least in that in the heatsink 330 the base 340 is formed from two distinct parts. In particular, the base 340 is formed from a base perimeter 349 and an insert base 353, which is part of a fin insert assembly 355. The base perimeter 349 is similar in general shape to the base 240 described above except with a socket 346 formed therein, wherein the socket 346 comprises an aperture extending all the way through the thickness of the base perimeter 349. The socket 346 is sized and shaped to receive the insert base 353. Note that in the exploded views the fin insert assembly 355 is shown above the base perimeter 349, but in some examples the fin insert assembly 355 may be inserted into the socket 346 from below, rather than from above. The insert base 353 may be coupled to the base perimeter 349 once inserted into the socket 346, for example by welding, brazing, friction fitting, adhesive, or other fastening/joining techniques. Once coupled, the base perimeter 349 and insert base 353 together form the base 340. A bottom face 343 of the base 340 thus comprises two sections, one of which is formed by a bottom face 343a of the base perimeter 349 and the other of which is formed by a bottom face 343b of the insert base 353.

As noted, the heatsink 330 includes a fin insert assembly 355 which includes the insert base 353. In addition, the fin insert assembly 355 includes a set of multiple fins 350 coupled to the insert base 353, as shown in FIG. 8 (only one of the illustrated fins 350 is labeled). The fins 350 are one example implementation of the protrusions 150. The fins 350 are relatively thin and planar sheets or plates of thermally conductive metal, such as aluminum, copper, etc. The fins 350 are oriented perpendicular to the insert base 353 and parallel to one another. As shown in FIG. 3, the fins 350 protrude from a top face (not labeled) of the insert base 353, which is opposite from the bottom face 343b. The fins 350 protrude from the top face along the height dimension of the heatsink 330 and also extend along the length dimension of the heatsink 330. Each pair of adjacent fins 350 defines a channel a therebetween. The fins 350 may be arranged in a one-dimensional array with positions thereof distributed across the width dimension of the heatsink 330. Although the fin positions are distributed across the width dimension, the fins 350 themselves extend longitudinally along the length dimension, as shown. In this example, the fins 350 are integrally connected to the insert base 353, forming one monolithic body, i.e., the fin insert assembly 355. For example, the insert base 353 and fins 350 may be integrally formed together by extrusion, skiving, casting, or other manufacturing processes. In some examples, the insert base 353 and the fins 350 are parts of the same monolith extruded metal body.

In this example, the fins 350 have a finer pitch (narrower inter-fin spacing) than the fins 250. But this is just one example, and in other examples, the fins 350 could have the same pitch as the fins 250, a coarser pitch (wider spacing) than the fins 250, or a finer pitch than that shown in FIGS. 8-10. Indeed, one benefit of using a fin insert assembly 355 that is separate from the base perimeter 349 is that it can be easy to customize the fins 350 to the particular application in which the heatsink 330 is being deployed. For example, multiple different fin insert assemblies 355 having differently configured fins 350 could be produced and the fin insert assembly 355 that best suits a particular application can be selected and coupled to the base perimeter 349 to form a heatsink 330 customized for that application. Another advantage may be that, in some examples, the fin insert assembly 355 may be formed from a different material than the base perimeter 349, which can allow for thermal performance and costs to be balanced (e.g., material with higher conductivity, such as copper, can be used for the insert assembly 355, while a less costly and less conductive material, such as aluminum, steel, zinc, etc., can be used for the base perimeter.

The base perimeter 349 includes mounting features (not labeled) similar to the mounting features 242 described above. In addition, the manifold 360 is coupled to the base perimeter 349 in the same fashion that manifold 260 is coupled to base 240. The manifold 360 may be similar to the manifold 260 described above, and thus duplicative description thereof is omitted.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. A heatsink for immersion cooling a processor of an information processing device, comprising:
a base comprising a first face configured to be thermally coupled to the processor in an installed state of the heatsink in the information processing device;
heat dissipating protrusions coupled to and protruding from a second face of the base; and
a manifold attached directly to the second face of the base adjacent the heat dissipating protrusions, wherein the manifold comprises an inlet and multiple outlets and is configured to, in a state of the heatsink installed in the information processing device immersed in a pool of liquid coolant of an immersion cooling tank, receive via the inlet an input stream of the liquid coolant and expel output streams of the liquid coolant towards the heat dissipating protrusions via the outlets.

2. The heatsink of claim 1,
wherein the heat dissipating protrusions comprise fins.

3. The heatsink of claim 2,
wherein the base and the fins are integrally connected.

4. The heatsink of claim 3,
wherein the base and the fins are part of an extruded metal body.

5. The heatsink of claim 2, comprising:
a base perimeter comprising a socket; and
an insert base inserted into the socket and coupled to the base perimeter, the insert base and the base perimeter together forming the base;
wherein the fins are coupled to the insert base.

6. The heatsink of claim 5,
wherein the fins are integrally connected to the insert base.

7. The heatsink of claim 5,
wherein the insert base and the base perimeter comprise different materials than one another.

8. The heatsink of claim 1,
wherein the base comprises mounting features configured to mount the heatsink to a system board of the information processing device.

9. The heatsink of claim 8,
wherein the system board comprises heatsink mounting features configured to mount an air-cooled heatsink to the system board; and
wherein the mounting features are configured to engage the heatsink mounting features to mount the immersion cooling heatsink to the system board in lieu of the air-cooled heatsink.

10. The heatsink of claim 9,
wherein the heat dissipating protrusions comprise fins, and the fins have a coarser pitch than air-cooled fins of the air-cooled heatsink.

11. The heatsink of claim 1,
wherein the manifold is removably attached to the base by fasteners.

12. The heatsink of claim 1,
wherein the manifold comprises a bottom part coupled to the base and a top part joined to the bottom part, the bottom part and the top part defining an interior chamber of the manifold therebetween.

13. The heatsink of claim 12,
wherein the bottom part and the top part are coupled together and to the base by fasteners that extend through the top part and the bottom part.

14. The heatsink of claim 1,
wherein the outlets comprise nozzles.

15. The heatsink of claim 1,
wherein the outlets are configured to direct the output streams to flow through channels extending between the heat dissipating protrusions.

16. An information processing device comprising:
a chassis;
a system board supported by the chassis and comprising a processor mounted thereto;
an immersion cooling heatsink mounted to the system board and comprising:
a base comprising a first face thermally coupled to the processor;
heat dissipating protrusions coupled to and protruding from a second face of the base; and
a manifold attached directly to the second face of the base adjacent the heat dissipating protrusions, wherein the manifold comprises an inlet and multiple outlets; and
a pump coupled to the chassis and fluidically coupled to the inlet of the manifold, wherein, in an immersed state of the information processing device in a pool of liquid coolant of an immersion tank, the pump is configured to draw in a flow of the liquid coolant from the pool and supply the flow as an input stream to the manifold via the inlet, and the outlets of the manifold are configured to expel output streams of the liquid coolant towards the heat dissipating protrusions.

17. The information processing device of claim 16,
wherein the heat dissipating protrusions comprise fins.

18. The information processing device of claim 17,
wherein the fins are integrally connected to the base.

19. The information processing device of claim 16,
wherein the system board comprises heatsink mounting features configured to mount an air-cooled heatsink to the system board; and
wherein the base comprises mounting features that engage the heatsink mounting features to mount the immersion cooling heatsink to the system board in lieu of the air-cooled heatsink.

20. An immersion cooling system, comprising:
an immersion cooling tank containing a pool of liquid coolant, the immersion cooling tank configured to receive multiple information processing devices immersed in the pool;
an information processing device immersed in the pool, the information processing device comprising:
a chassis;
a system board supported by the chassis and comprising a processor mounted thereto; and
an immersion cooling heatsink mounted to the system board and comprising:
a base comprising a first face thermally coupled to the processor;
heat dissipating protrusions coupled to and protruding from a second face of the base; and
a manifold attached directly to the second face of the base adjacent the heat dissipating protrusions, wherein the manifold comprises an inlet and multiple outlets; and
a pump fluidically coupled to the inlet of the manifold and configured to draw in a flow of the liquid coolant from the pool and supply the flow as an input stream to the manifold via the inlet, wherein the outlets of the manifold are configured to expel output streams of the liquid coolant towards the heat dissipating protrusions.
